(19) United States
(12) Patent Application Publication
(10) Pub. No.: US 2024/0112747 A1
(43) Pub. Date: Apr. 4, 2024

(54) SIGNAL INTERFERENCE TESTING USING RELIABLE READ WRITE INTERFACE

(71) Applicant: Advanced Micro Devices, Inc., Santa Clara, CA (US)

(72) Inventors: Tahsin Askar, Round Rock, TX (US); Naveen Davanam, Austin, TX (US); Kedarnath Balakrishnan, Bangalore (IN); Kevin M. Brandl, Austin, TX (US); James R. Magro, Lakeway, TX (US)

(73) Assignee: Advanced Micro Devices, Inc., Santa Clara, CA (US)

(21) Appl. No.: 17/957,808

(22) Filed: Sep. 30, 2022

(51) Int. Cl. G11C 29/10

(52) U.S. Cl. CPC G11C 29/10

(57) ABSTRACT

A memory controller includes a first arbiter for selecting memory commands for dispatch to a memory over a first channel, a second arbiter for selecting memory commands for dispatch to the memory over a second channel, and a test circuit. The test circuit generates a respective testing sequence of read commands and write commands for each of the first channel and second channel, and causes the testing sequences to be transmitted over the first and second channels at least partially overlapping in time without selection by the first or second arbiters.

### BACKGROUND

Computer systems typically use inexpensive and high density dynamic random access memory (DRAM) chips for main memory. Most DRAM chips sold today are compatible with various double data rate (DDR) DRAM standards promulgated by the Joint Electron Devices Engineering Council (JEDEC). DDR DRAMs use conventional DRAM memory cell arrays with high-speed access circuits to achieve high transfer rates and to improve the utilization of the memory bus. A DDR memory controller may interface with multiple DDR channels in order to accommodate more DRAM modules, and to exchange data with the memory faster than using a single channel. Further, modern server systems often include multiple memory controllers in a single data processor. For example, some modern server processors include eight or twelve memory controllers each connected to a respective DDR channel.

With multiple DDR channels in the same system, cross-talk and other noise associated with the data transmission lines of the memory channels may cause transmissions on one channel to interfere with those on another channel, typically a channel with physically adjacent transmission lines such as printed circuit board traces. However, the link testing and physical layer circuit (PHY) training processes typically do not account for such crosstalk and noise. Generally, it is challenging to detect and measure crosstalk and noise using regular system level traffic, because of the unpredictable nature of normal traffic, and the reordering of commands as they are selected by the arbiter.

### BRIEF DESCRIPTION OF THE DRAWINGS

FIG. 1 illustrates in block diagram form a data processing system according to the prior art;

FIG. 2 illustrates in block diagram form an accelerated processing unit (APU) suitable for use in a data processing system according to some embodiments;

FIG. 3 illustrates in block diagram form a memory controller and associated physical interface (PHY) suitable for use in the APU of FIG. 2 according to some embodiments;

FIG. 4 illustrates in block diagram form another memory controller and associated PHY suitable for use in the APU of FIG. 2 according to some embodiments;

FIG. 5 illustrates in block diagram form a memory controller according to some embodiments;

FIG. 6 illustrates in block diagram form reliable read-write training engine (RRW/TE) coupled to a memory PHY according to some embodiments; and

FIG. 7 is a flow diagram of a process for operating a RRW/TE according to some embodiments.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

A memory controller includes a first arbiter for selecting memory commands for dispatch to a memory over a first channel, a second arbiter for selecting memory commands for dispatch to the memory over a second channel, and a test circuit. The test circuit generates a respective testing sequence of read commands and write commands for each of the first channel and second channel, and causes the testing sequences to be transmitted over the first and second channels at least partially overlapping in time without selection by the first or second arbiters.

A method tests two memory channels simultaneously. The method includes generating a first testing sequence of read commands and write commands for a first memory channel, and generating a second testing sequence of read commands and write commands for a second memory channel. The method includes causing the first testing sequence to be transmitted intact over the first memory channel, and causing the second testing sequence to be transmitted intact over the second memory channel at least partially overlapping the first testing sequence in time.

A data processing system includes a dynamic random-access memory (DRAM) and a memory controller coupled to the memory over a memory bus. The memory controller includes a first arbiter for selecting memory commands for dispatch to a memory over a first channel, a second arbiter for selecting memory commands for dispatch to the memory over a second channel, and a test circuit. The test circuit generates a respective testing sequence of read commands and write commands for each of the first channel and second channel, and causes the testing sequences to be transmitted over the first and second channels at least partially overlapping in time without selection by the first or second arbiters.

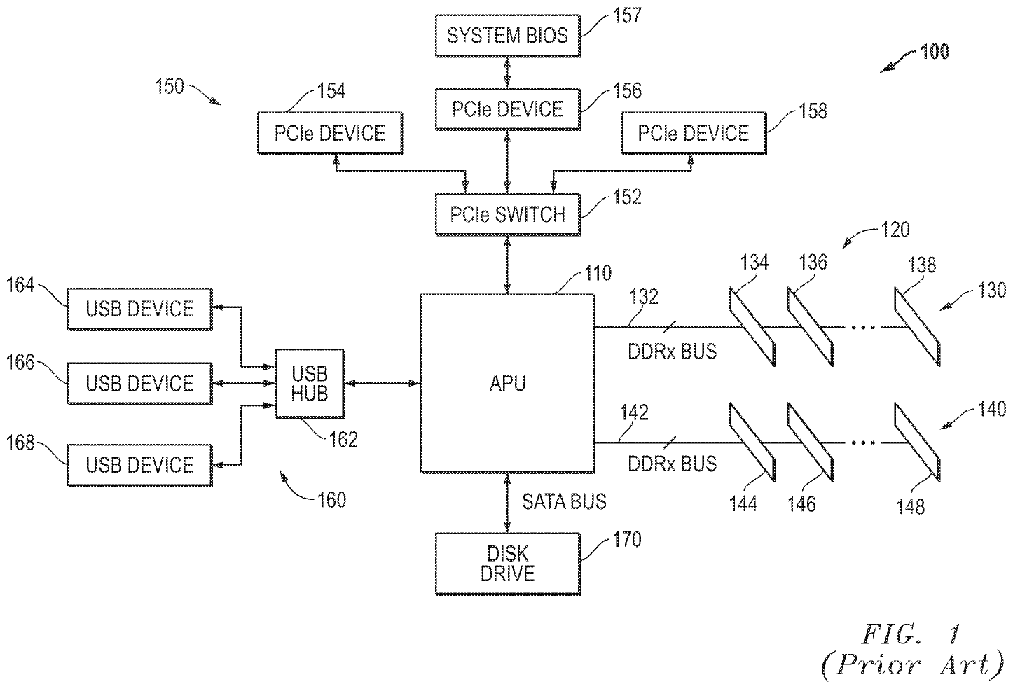

FIG. 1 illustrates in block diagram form a data processing system 100 according to the prior art. Data processing system 100 includes generally a data processor 110 in the form of an accelerated processing unit (APU), a memory system 120, a peripheral component interconnect express (PCIe) system 150, a universal serial bus (USB) system 160, and a disk drive 170. Data processor 110 operates as the central processing unit (CPU) of data processing system 100 and provides various buses and interfaces useful in modern computer systems. These interfaces include two double data rate (DDRx) memory channels, a PCIe root complex for connection to a PCIe link, a USB controller for connection to a USB network, and an interface to a Serial Advanced Technology Attachment (SATA) mass storage device.

Memory system 120 includes a memory channel 130 and a memory channel 140. Memory channel 130 includes a set of dual inline memory modules (DIMMs) connected to a DDRx bus 132, including representative DIMMs 134, 136, and 138 that in this example correspond to separate ranks. Likewise memory channel 140 includes a set of DIMMs connected to a DDRx bus 142, including representative DIMMs 144, 146, and 148.

PCIe system 150 includes a PCIe switch 152 connected to the PCIe root complex in data processor 110, a PCIe device 154, a PCIe device 156, and a PCIe device 158. PCIe device 156 in turn is connected to a system basic input/output system (BIOS) memory 157. System BIOS memory 157 can be any of a variety of non-volatile memory types, such as read-only memory (ROM), flash electrically erasable programmable ROM (EEPROM), and the like.

USB system 160 includes a USB hub 162 connected to a USB master in data processor 110, and representative USB devices 164, 166, and 168 each connected to USB hub 162. USB devices 164, 166, and 168 could be devices such as a keyboard, a mouse, a flash EEPROM port, and the like.

Disk drive 170 is connected to data processor 110 over a SATA bus and provides mass storage for the operating system, application programs, application files, and the like.

Data processing system 100 is suitable for use in modern computing applications by providing a memory channel 130 and a memory channel 140. Each of memory channels 130 and 140 can connect to DDR memories such as DDR version four (DDR4), low power DDR4 (LPDDR4), graphics DDR version five (GDDR5), and high bandwidth memory (HBM), and can be adapted for future memory technologies. These memories provide high bus bandwidth and high speed operation. At the same time, they also provide low power modes to save power for battery-powered applications such as laptop computers, and also provide built-in thermal monitoring.

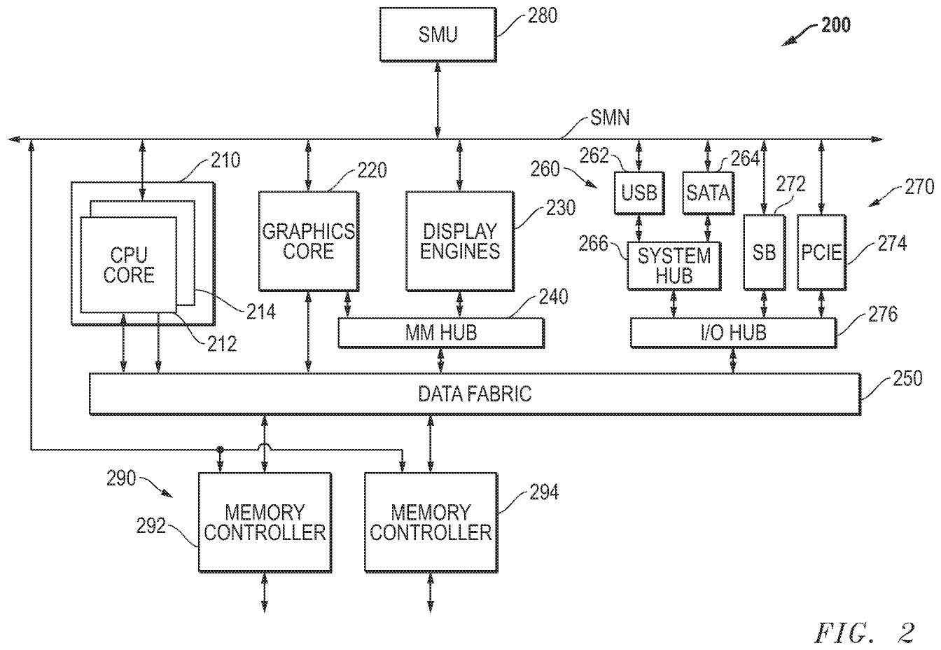

FIG. 2 illustrates in block diagram form an APU 200 suitable for use in data processing system 100 of FIG. 1 and other modern data processing systems. APU 200 includes generally a central processing unit (CPU) core complex 210, a graphics core 220, a set of display engines 230, a memory management hub 240, a data fabric 250, a set of peripheral controllers 260, a set of peripheral bus controllers 270, a system management unit (SMU) 280, and a set of memory controllers 290.

CPU core complex 210 includes a CPU core 212 and a CPU core 214. In this example, CPU core complex 210 includes two CPU cores, but in other embodiments CPU core complex 210 can include an arbitrary number of CPU cores. Each of CPU cores 212 and 214 is bidirectionally connected to a system management network (SMN), which forms a control fabric, and to data fabric 250, and is capable of providing memory access requests to data fabric 250. Each of CPU cores 212 and 214 may be unitary cores, or may further be a core complex with two or more unitary cores sharing certain resources such as caches.

Graphics core 220 is a high performance graphics processing unit (GPU) capable of performing graphics operations such as vertex processing, fragment processing, shading, texture blending, and the like in a highly integrated and parallel fashion. Graphics core 220 is bidirectionally connected to the SMN and to data fabric 250, and is capable of providing memory access requests to data fabric 250. In this regard, APU 200 may either support a unified memory architecture in which CPU core complex 210 and graphics core 220 share the same memory space, or a memory architecture in which CPU core complex 210 and graphics core 220 share a portion of the memory space, while graphics core 220 also uses a private graphics memory not accessible by CPU core complex 210.

Display engines 230 render and rasterize objects generated by graphics core 220 for display on a monitor. Graphics core 220 and display engines 230 are bidirectionally connected to a common memory management hub 240 for uniform translation into appropriate addresses in memory system 120, and memory management hub 240 is bidirectionally connected to data fabric 250 for generating such memory accesses and receiving read data returned from the memory system.

Data fabric 250 includes a crossbar switch for routing memory access requests and memory responses between any memory accessing agent and memory controllers 290. It also includes a system memory map, defined by BIOS, for determining destinations of memory accesses based on the system configuration, as well as buffers for each virtual connection.

Peripheral controllers 260 include a USB controller 262 and a SATA interface controller 264, each of which is bidirectionally connected to a system hub 266 and to the SMN bus. These two controllers are merely exemplary of peripheral controllers that may be used in APU 200.

Peripheral bus controllers 270 include a system controller or “Southbridge” (SB) 272 and a PCIe controller 274, each of which is bidirectionally connected to an input/output (I/O) hub 276 and to the SMN bus. I/O hub 276 is also bidirectionally connected to system hub 266 and to data fabric 250. Thus for example a CPU core can program registers in USB controller 262, SATA interface controller 264, SB 272, or PCIe controller 274 through accesses that data fabric 250 routes through I/O hub 276.

SMU 280 is a local controller that controls the operation of the resources on APU 200 and synchronizes communication among them. SMU 280 manages power-up sequencing of the various processors on APU 200 and controls multiple off-chip devices via reset, enable and other signals. SMU 280 includes one or more clock sources not shown in FIG. 2, such as a phase locked loop (PLL), to provide clock signals for each of the components of APU 200. SMU 280 also manages power for the various processors and other functional blocks, and may receive measured power consumption values from CPU cores 212 and 214 and graphics core 220 to determine appropriate power states.

APU 200 also implements various system monitoring and power saving functions. In particular one system monitoring function is thermal monitoring. For example, if APU 200 becomes hot, then SMU 280 can reduce the frequency and voltage of CPU cores 212 and 214 and/or graphics core 220. If APU 200 becomes too hot, then it can be shut down entirely. Thermal events can also be received from external sensors by SMU 280 via the SMN bus, and SMU 280 can reduce the clock frequency and/or power supply voltage in response.

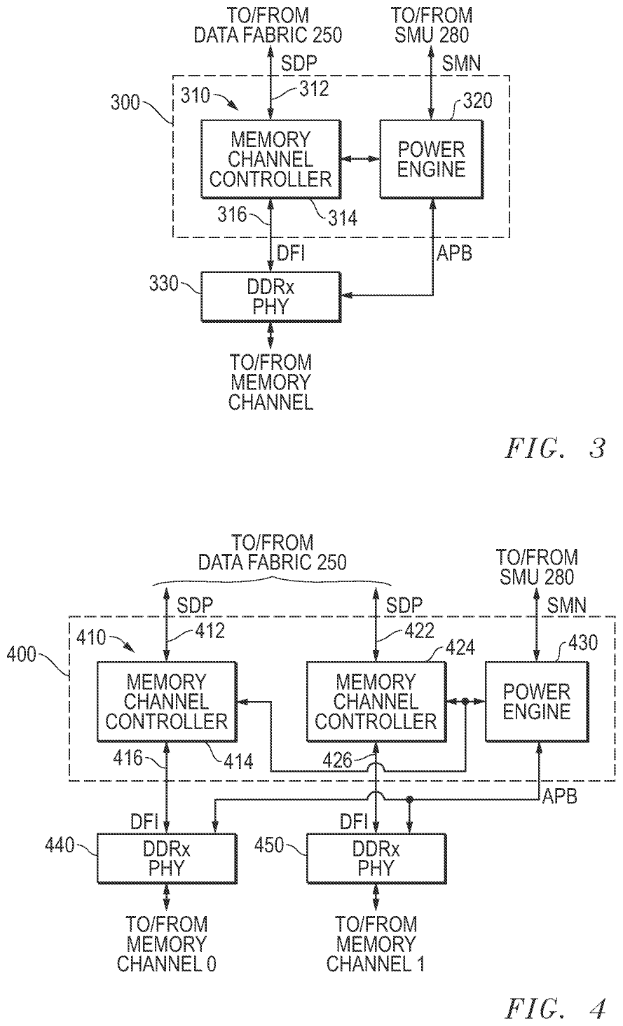

FIG. 3 illustrates in block diagram form a memory controller 300 and an associated physical interface (PHY) 330 suitable for use in APU 200 of FIG. 2 according to some embodiments. Memory controller 300 includes a memory channel 310 and a power engine 320. Memory channel 310 includes a host interface 312, a memory channel controller 314, and a physical interface 316. Host interface 312 bidirectionally connects memory channel controller 314 to data fabric 250 over a scalable data port (SDP). Physical interface 316 bidirectionally connects memory channel controller 314 to PHY 330 over a bus that conforms to the DDR-PHY Interface Specification (DFI). Power engine 320 is bidirectionally connected to SMU 280 over the SMN bus, to PHY 330 over the Advanced Peripheral Bus (APB), and is also bidirectionally connected to memory channel controller 314. PHY 330 has a bidirectional connection to a memory channel such as memory channel 130 or memory channel 140 of FIG. 1. Memory controller 300 is an instantiation of a memory controller for a single memory channel using a single memory channel controller 314, and has a power engine 320 to control operation of memory channel controller 314 in a manner that will be described further below.

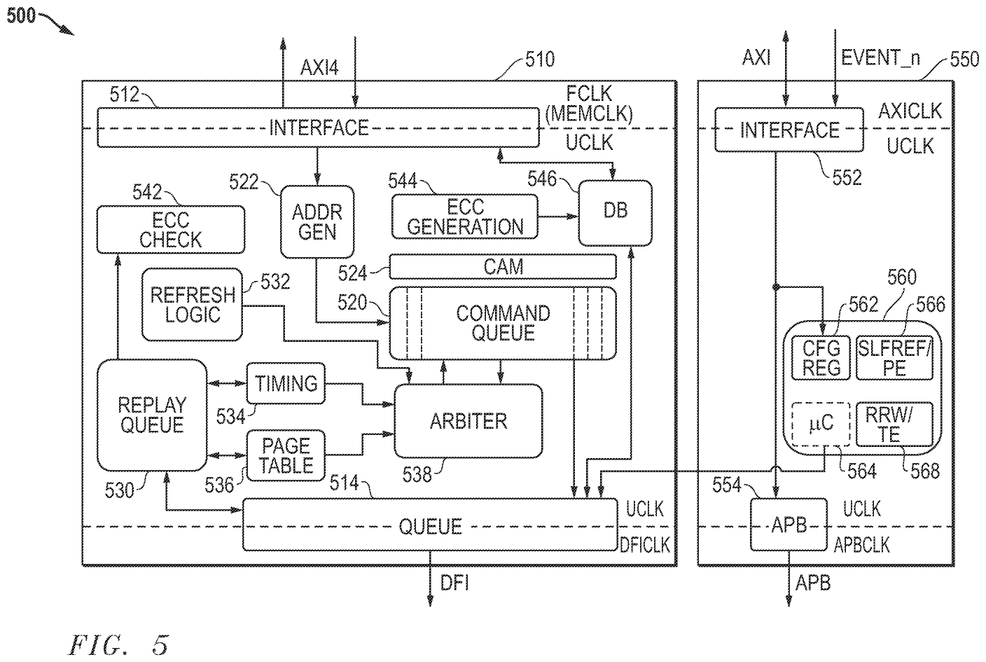

FIG. 4 illustrates in block diagram form another memory controller 400 and associated PHYs 440 and 450 suitable for use in APU 200 of FIG. 2 according to some embodiments. Memory controller 400 includes a memory channels 410 and 420 and a power engine 430. Memory channel 410 includes a host interface 412, a memory channel controller 414, and a physical interface 416. Host interface 412 bidirectionally connects memory channel controller 414 to data fabric 250 over an SDP. Physical interface 416 bidirectionally connects memory channel controller 414 to PHY 440, and conforms to the DFI Specification. Memory channel 420 includes a host interface 422, a memory channel controller 424, and a physical interface 426. Host interface 422 bidirectionally connects memory channel controller 424 to data fabric 250 over another SDP. Physical interface 426 bidirectionally connects memory channel controller 424 to PHY 450, and conforms to the DFI Specification. Power engine 430 is bidirectionally connected to SMU 280 over the SMN bus, to PHYs 440 and 450 over the APB, and is also bidirectionally connected to memory channel controllers 414 and 424. PHY 440 has a bidirectional connection to a memory channel such as memory channel 130 of FIG. 1. PHY 450 has a bidirectional connection to a memory channel such as memory channel 140 of FIG. 1. Memory controller 400 is an instantiation of a memory controller having two memory channel controllers and uses a shared power engine 430 to control operation of both memory channel controller 414 and memory channel controller 424 in a manner that will be described further below.

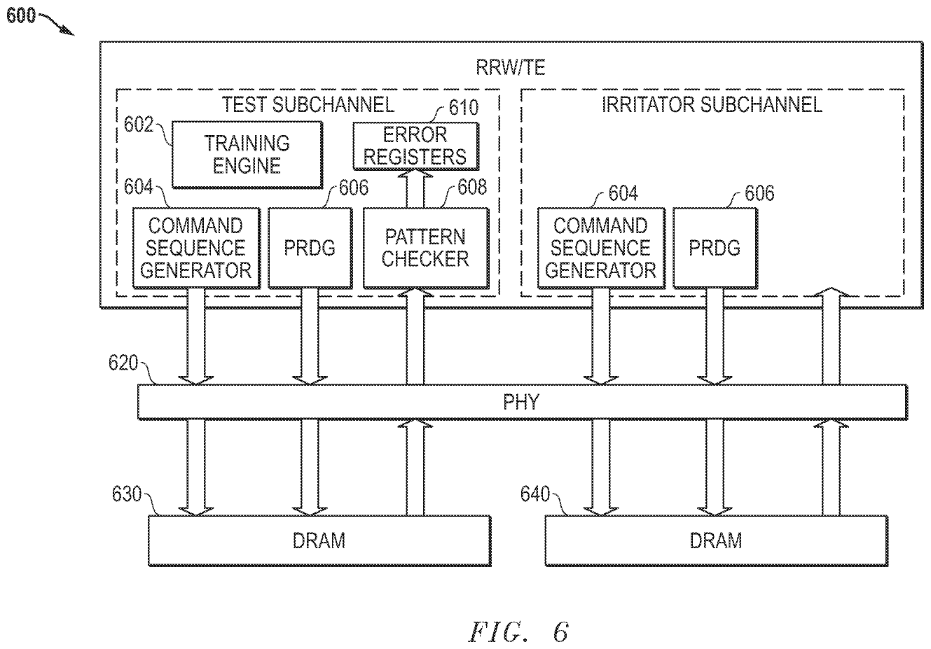

FIG. 5 illustrates in block diagram form a memory controller 500 according to some embodiments. Memory controller 500 includes a memory channel controller 510 and a power controller 550. Memory channel controller 510 includes an interface 512, a queue 514, a command queue 520, an address generator 522, a content addressable memory (CAM) 524, a replay queue 530, a refresh logic block 532, a timing block 534, a page table 536, an arbiter 538, an error correction code (ECC) check block 542, an ECC generation block 544, and a data buffer (DB) 546.

Interface 512 has a first bidirectional connection to data fabric 250 over an external bus, and has an output. In memory controller 500, this external bus is compatible with the advanced extensible interface such as “AXI4”, but can be other types of interfaces in other embodiments. Interface 512 translates memory access requests from a first clock domain known as the FCLK (or MEMCLK) domain to a second clock domain internal to memory controller 500 known as the UCLK domain. Similarly, queue 514 provides memory accesses from the UCLK domain to the DFICLK domain associated with the DFI interface.

Address generator 522 decodes addresses of memory access requests received from data fabric 250 over the AXI4 bus. The memory access requests include access addresses in the physical address space represented in as a normalized address. Address generator 522 converts the normalized addresses into a format that can be used to address the actual memory devices in memory system 120, as well as to efficiently schedule related accesses. This format includes a region identifier that associates the memory access request with a particular rank, a row address, a column address, a bank address, and a bank group. On startup, the system BIOS queries the memory devices in memory system 120 to determine their size and configuration, and programs a set of configuration registers associated with address generator 522. Address generator 522 uses the configuration stored in the configuration registers to translate the normalized addresses into the appropriate format. Command queue 520 is a queue of memory access requests received from the memory accessing agents in data processing system 100, such as CPU cores 212 and 214 and graphics core 220. Command queue 520 stores the address fields decoded by address generator 522 as well other address information that allows arbiter 538 to select memory accesses efficiently, including access type and quality of service (QoS) identifiers. CAM 524 includes information to enforce ordering rules, such as write after write (WAW) and read after write (RAW) ordering rules.

Replay queue 530 is a temporary queue for storing memory accesses picked by arbiter 538 that are awaiting responses, such as address and command parity responses, write cyclic redundancy check (CRC) responses for DDR4 DRAM or write and read CRC responses for GDDR5 DRAM. Replay queue 530 accesses ECC check block 542 to determine whether the returned ECC is correct or indicates an error. Replay queue 530 allows the accesses to be replayed in the case of a parity or CRC error of one of these cycles.

Refresh logic 532 includes state machines for various powerdown, refresh, and termination resistance (ZQ) calibration cycles that are generated separately from normal read and write memory access requests received from memory accessing agents. For example, if a memory rank is in precharge powerdown, it must be periodically awakened to run refresh cycles. Refresh logic 532 generates auto-refresh commands periodically to prevent data errors caused by leaking of charge off storage capacitors of memory cells in DRAM chips. In addition, refresh logic 532 periodically calibrates ZQ to prevent mismatch in on-die termination resistance due to thermal changes in the system. Refresh logic 532 also decides when to put DRAM devices in different power down modes.

Arbiter 538 is bidirectionally connected to command queue 520 and is the heart of memory channel controller 510. It improves efficiency by intelligent scheduling of accesses to improve the usage of the memory bus. Arbiter 538 uses timing block 534 to enforce proper timing relationships by determining whether certain accesses in command queue 520 are eligible for issuance based on DRAM timing parameters. For example, each DRAM has a minimum specified time between activate commands to the same bank, known as “t.sub.RC”. Timing block 534 maintains a set of counters that determine eligibility based on this and other timing parameters specified in the JEDEC specification, and is bidirectionally connected to replay queue 530. Page table 536 maintains state information about active pages in each bank and rank of the memory channel for arbiter 538, and is bidirectionally connected to replay queue 530.

In response to write memory access requests received from interface 512, ECC generation block 544 computes an ECC according to the write data. DB 546 stores the write data and ECC for received memory access requests. It outputs the combined write data/ECC to queue 514 when arbiter 538 picks the corresponding write access for dispatch to the memory channel.

Power controller 550 includes an interface 552 to an advanced extensible interface, version one (AXI), an APB interface 554, and a power engine 560. Interface 552 has a first bidirectional connection to the SMN, which includes an input for receiving an event signal labeled “EVENT_n” shown separately in FIG. 5, and an output. APB interface 554 has an input connected to the output of interface 552, and an output for connection to a PHY over an APB. Power engine 560 has an input connected to the output of interface 552, and an output connected to an input of queue 514. Power engine 560 includes a set of configuration registers 562, a microcontroller 564, a self refresh controller (SLFREF/PE) 566, and a reliable read/write training engine (RRW/TE) 568. Configuration registers 562 are programmed over the AXI bus, and store configuration information to control the operation of various blocks in memory controller 500. Accordingly, configuration registers 562 have outputs connected to these blocks that are not shown in detail in FIG. 5. Self refresh controller 566 is an engine that allows the manual generation of refreshes in addition to the automatic generation of refreshes by refresh logic 532. Reliable read/write training engine 568 provides a continuous memory access stream to memory or I/O devices for such purposes as DDR interface read latency training and loopback testing.

Memory channel controller 510 includes circuitry that allows it to pick memory accesses for dispatch to the associated memory channel. In order to make the desired arbitration decisions, address generator 522 decodes the address information into predecoded information including rank, row address, column address, bank address, and bank group in the memory system, and command queue 520 stores the predecoded information. Configuration registers 562 store configuration information to determine how address generator 522 decodes the received address information. Arbiter 538 uses the decoded address information, timing eligibility information indicated by timing block 534, and active page information indicated by page table 536 to efficiently schedule memory accesses while observing other criteria such as QoS requirements. For example, arbiter 538 implements a preference for accesses to open pages to avoid the overhead of precharge and activation commands required to change memory pages, and hides overhead accesses to one bank by interleaving them with read and write accesses to another bank. In particular during normal operation, arbiter 538 may decide to keeps pages open in different banks until they are required to be precharged prior to selecting a different page. Arbiter 538 supports issuing of either one command or two commands per memory controller clock cycle.

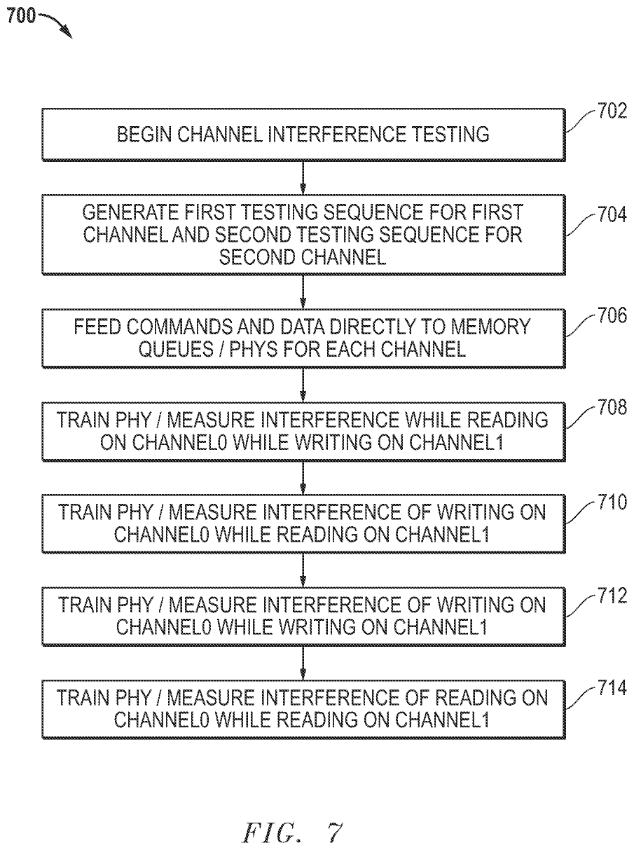

FIG. 6 illustrates in block diagram form a reliable read/write training engine (RRW/TE) 600 according coupled to a memory PHY to some embodiments. RRW/TE 600 generally is able to provide selected commands or a continuous memory access stream to memory or I/O devices for such purposes as DDR interface read and write data eye training. In the depicted arrangement, the channels are subchannels accessed over a memory PHY 620. In this embodiment, RRW/TE is part of a power engine such as power engine 430 (FIG. 4), and is bidirectionally connected to two memory channel controllers and their PHY circuits interfaces in the arrangement depicted in FIG. 4, and is generally embodied in the same integrated circuit or SOC with the associated memory controllers.

In this embodiment, RRW/TE 600 has a bidirectional connection to the memory interface queue for each memory channel. RRW/TE 600 has a first channel interface circuit labelled “TEST SUBCHANNEL” and a second channel interface circuit labelled “IRRITATOR SUBCHANNEL”, for injecting streams of memory access commands and receiving results thereof. In other embodiments, similar functionality may be achieved by connecting to the PHY interface for different memory channel controllers (e.g., FIGS. 4, 440 and 450). The TEST SUBCHANNEL and IRRITATOR SUBCHANNEL circuits are configurable to be used with either subchannel. For example, in one scenario, the TEST SUBCHANNEL interface circuit communicates with a DRAM 630 for testing, and the IRRITATOR SUBCHANNEL circuit communicates with a DRAM 640 for testing.

Generally, the TEST SUBCHANNEL interface circuit provides a sequence of test commands and data to a first DRAM 630 over PHY 620. RRW/TE 600 includes a training engine 602, a command sequence generator 604, and a pseudo-random data generator circuit (PRDG) 606, a pattern checker 608, and a series of error registers 610. The IRRITATOR SUBCHANNEL is for providing sequences of commands and data for testing interference between the two sub-channels, and includes a command sequence 604 and a PRDG 606, in communication with training engine 602 for receiving instructions.

Training engine 602 is a digital logic circuit that may be implemented as a microcontroller or state machine and generally directs training of PHY circuits for each channel. Training engine 602 is connected to control the other parts of RRW/TE for implementing testing. In addition to such training, training engine 602 also directs testing of interference between the two channels in various scenarios including combinations of reading and writing data on both memory channels simultaneously.

Command sequence generator 604 has an output connected to PHY 620 and control inputs connected to training engine 602. In this embodiment, command sequence generator 604 is a digital logic circuit which produces a stream of write and read commands for performing test sequences. Write commands are accompanied by write data produced by PRDG 606. Command sequence generator 604 may be implemented as a state machine or with firmware executed by training engine 602.

PRDG 606 includes a number of pseudo-random data sequence (PRDS) generators for producing data to be written to respective memories over both memory channels, and an output to PHY 620. Preferably, each PRDS generator is constructed with a linear-feedback shift register (LFSR) with a predetermined set of feedback taps selected to provide desired pseudo-random properties in a generated data stream. As such, the data stream produced is predictable and repeatable.

Pattern checker 608 includes comparison logic for comparing data received from the respective DRAM based on read commands with the PRDS originally written to the respective DRAM using write commands. Pattern checker 608 has control inputs from training engine 602, and input from PHY 620, and inputs from PRDG 606 for receiving the data sequences to be compared. Pattern checker 608 has outputs connected to error registers 610 for recording errors detected by pattern checker 608.

In operation, RRW/TE 600 generates a respective testing sequence of read commands and write commands for each of the first channel and second channel, and causes the testing sequences to be transmitted over the first and second channels at least partially overlapping in time without selection by the first or second arbiters. The test sequences may generally include transmitting data to and from DRAM 630 as the test subchannel while transmitting to and from DRAM 640 as the irritator subchannel producing potential interference, and then transmitting to and from DRAM 640 as the test subchannel, while the channel to DRAM 630 is the irritator subchannel. As such, the IRRITATOR SUBCHANNEL circuit does not require a pattern checker or error registers, but may include them in some embodiments to make reconfiguration of the test circuit easier. Preferably, a multiplexer is employed to re-route data transmissions to and from each of DRAM 630 and DRAM 640 from the TEST SUBCHANNEL circuit and the IRRITATOR SUBCHANNEL circuit. The test sequences are fed to the respective PHY without involvement of the normal memory controller and arbiter selection process, which could change the order and timing of commands sequences. This direct injection guarantees that the desired data and commands are transmitted on the memory channels in the precisely desired relationship for testing and training. While a single PHY circuit 620 is shown including two sub-channels, RRW/TE 600 may also be used in systems with two separate PHY circuits.

In this implementation, both the test and irritator channels can be configured independently by training engine 602 using the following configurations. A command type setting “CmdType” configures TEST SUBCHANNEL circuit and the IRRITATOR SUBCHANNEL circuits to perform write commands, read commands, or alternating write and read commands. A “Cmd Target” configures TEST SUBCHANNEL circuit and the IRRITATOR SUBCHANNEL circuits to issue a stream of commands beginning with the address in an address register “Target A”, or issue alternating addresses in Target A and another address register “Target B”. A “DataPatGenSel” configures the type of data pattern sent, e.g. PRBS or fixed pattern. A “DQ Mask Control per DQ” setting allows for masking individual DQ pins for the received data, in order to isolate errors from selected pins, including ECC and data mask/data bus inversion (DM/DBI) pins for loopback functions. A “StopOnErr” instructs the configures TEST SUBCHANNEL circuit and the IRRITATOR SUBCHANNEL circuits to halt the RRW/TE run if an error is encountered. A “Command Count” setting configures the number of write and read (WR/RD) commands that will be issued, including a setting of zero for generating commands indefinitely until halted. A “Bubble Count setting sets a CAS to CAS command separation in memclock cycles. A “Command Stream Length” setting controls the number of commands to issue in a test sequence before inserting bubbles or gaps. A “ActPchgGenEn” setting enables automatically issuing an ACT command before the WR/RD stream, and issues a precharge (PRE) command after the WR/RD stream. The number of clock cycles between ACT and WR/RD, as well as between WR/RD and PRE needs to be specified in a setting ActPchgCmdMin[5:0].

By providing ability to precisely control traffic on one channel, the irritator channel, while testing the other channel, RRW/TE 600 overcomes the difficulties of detecting and measuring cross-talk and noise between channels.

FIG. 7 shows a flow diagram 700 of a process for operating a RRW/TE according to some embodiments. The depicted process is suitable for use with RRW/TE 600 of FIG. 6 or other suitable RRW/TE circuits in a data processing system with multiple memory channels.

The process begins at block 702 where the RRW/TE begins channel interference testing. Preferably, the testing is performed during the system initialization or power-on self test (POST) sequence, but in some implementations the testing is used during re-training periods for the memory channels. In some embodiments, the testing is initiated by a system control processor commanding RRW/TE 600 over its AXI interface (FIG. 5, 552).

At block 704, training engine 602 executes instructions from program memory 606 for performing training sequences. Sequences include operating various PRDS generators in command sequence generator 604 to generate data, and producing sequence of commands with command sequence generator 604. In particular, a first testing sequence including commands and associated data is generated for the first memory channel, and a second testing sequence including commands and associated data is generated for the second memory channel. At block 706, the RRW/TE feeds commands and data for transmission over both channels. The transmission is overlapping or simultaneous, such that interference between channels can be measured.

As shown at block 708, the process may include performing training of I/O circuitry of the PHY while performing the testing sequence, or it may measure interference between the two channels while performing the testing sequence. Block 708 performs training or interference measurements while reading on the first memory channel and writing on the second memory channel. Measuring interference may include tracking bit error rates, bus signaling errors, and/or reading detailed data from I/O circuitry in the PHY concerning signal quality parameters and timing parameters.

Block 710 performs similar training or interference measurements while writing on the first memory channel and reading on the second memory channel. Block 712 perform training or interference measurements while writing on both memory channels, and block 714 performs training or interference measurements while reading on both memory channels.

Thus, various embodiments of a reliable read/write training engine, a system, an integrated circuit, and a method have been described. The RRW/TE, system, integrated circuit, and method provide several advantages for testing and configuring I/O signaling in systems with multiple memory channels. The ability to insert or inject a known set of commands and pseudo-random data to multiple channels simultaneously allows for precise testing and training for signal interference to be produced outside of a laboratory. The typical command chain through the memory controller and its arbiter is bypassed in a controllable manner for multiple memory controllers simultaneously. Such techniques enable such testing to be performed at system boot up, or during operation of the system, thus allowing for interference to be measured or accounted for in the systems operating conditions. Further, as the memory controller and I/O circuits age and degrade, such testing are performed and adjustments made to I/O signaling parameters.

The circuits of FIGS. 5 and 6 may be implemented with various combinations of hardware and software. For example, the hardware circuitry may include priority encoders, finite state machines, programmable logic arrays (PLAs), and the like, and RRW/TE could be implemented with a microcontroller executing stored program instructions to evaluate the relative timing eligibility of the pending commands. In this case some of the instructions may be stored in a non-transitory computer memory or computer readable storage medium for execution by the microcontroller. In various embodiments, the non-transitory computer readable storage medium includes a magnetic or optical disk storage device, solid-state storage devices such as Flash memory, or other non-volatile memory device or devices. The computer readable instructions stored on the non-transitory computer readable storage medium may be in source code, assembly language code, object code, or other instruction format that is interpreted and/or executable by one or more processors.

APU 200 of FIG. 2 or memory controller 500 of FIG. 5, or RRW/TE 600 of FIG. 6 may be described or represented by a computer accessible data structure in the form of a database or other data structure which can be read by a program and used, directly or indirectly, to fabricate integrated circuits. For example, this data structure may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates that also represent the functionality of the hardware comprising integrated circuits. The netlist may then be placed and routed to produce a data set describing geometric shapes to be applied to masks. The masks may then be used in various semiconductor fabrication steps to produce the integrated circuits. Alternatively, the database on the computer accessible storage medium may be the netlist (with or without the synthesis library) or the data set, as desired, or Graphic Data System (GDS) II data.

While particular embodiments have been described, various modifications to these embodiments will be apparent to those skilled in the art. For example, the internal architecture of memory channel controller 510 and/or power engine 550 may vary in different embodiments. Memory controller 500 may interface to other types of memory besides DDRx memory, such as high bandwidth memory (HBM), RAMbus DRAM (RDRAM), and the like. While the illustrated embodiment showed each rank of memory corresponding to separate DIMMs, in other embodiments each DIMM can support multiple ranks.

Accordingly, it is intended by the appended claims to cover all modifications of the disclosed embodiments that fall within the scope of the disclosed embodiments.

What is claimed is:

1. A memory controller comprising:
a first arbiter for selecting memory commands for dispatch to a memory over a first channel;
a second arbiter for selecting memory commands for dispatch to the memory over a second channel; and
a test circuit for generating a respective testing sequence of read commands and write commands for each of the first channel and second channel, and causing the testing sequences to be transmitted over the first and second channels at least partially overlapping in time without selection by the first or second arbiters.

2. The memory controller of claim 1, wherein the test circuit further comprises a pseudo-random data generator producing pseudo-random data which is written to the memory with write commands in the testing sequences.

3. The memory controller of claim 1, further wherein the testing circuit further measures interference between the first and second channels while the testing sequences overlap in time.

4. The memory controller of claim 1, further comprising:
a training circuit for training respective physical layer circuits of the first and second channels, the training circuit performing at least one training operation while the testing sequences overlap in time.

5. The memory controller of claim 1, wherein the test circuit generates testing sequences including read commands on one of the channels while write commands are on the other channel.

6. The memory controller of claim 1, wherein the test circuit generates testing sequences including read commands on one of the channels while read commands are on the other channel.

7. The memory controller of claim 1, wherein the test circuit generates testing sequences including write commands on one of the channels while write commands are on the other channel.

8. A method for testing two memory channels simultaneously, the method comprising:
generating a first testing sequence of read commands and write commands for a first memory channel;
generating a second testing sequence of read commands and write commands for a second memory channel;
causing the first testing sequence to be transmitted intact over the first memory channel; and
causing the second testing sequence to be transmitted intact over the second memory channel at least partially overlapping the first testing sequence in time.

9. The method of claim 8, further comprising:
producing pseudo-random data which is written to the memory with write commands in the testing sequences.

10. The method of claim 8, further comprising:
measuring interference between the first and second channels while the testing sequences overlap in time.

11. The method of claim 8, further comprising:
measuring interference between a read operation on one channel and a write operation on the other channel while the testing sequences overlap in time.

12. The method of claim 8, further comprising:
performing at least one training operation while the testing sequences overlap in time.

13. The method of claim 8, further comprising:
generating testing sequences including read commands on one of the channels while read commands are on the other channel.

14. The method of claim 8, further comprising:
generating testing sequences including write commands on one of the channels while write commands are on the other channel.

15. A data processing system comprising
a dynamic random-access memory (DRAM); and
a memory controller coupled to the memory over a memory bus, the memory controller including:
a first arbiter for selecting memory commands for dispatch to a memory over a first channel;
a second arbiter for selecting memory commands for dispatch to the memory over a second channel; and
a test circuit for generating a respective testing sequence of read commands and write commands for each of the first channel and second channel, and causing the testing sequences to be transmitted over the first and second channels at least partially overlapping in time without selection by the first or second arbiters.

16. The data processing system of claim 15, wherein the test circuit further comprises a pseudo-random data generator producing pseudo-random data which is written to the memory with write commands in the testing sequences.

17. The data processing system of claim 15, wherein the testing circuit further measures interference between the first and second channels while the testing sequences overlap in time.

18. The data processing system of claim 15, further comprising:
a training circuit for training respective physical layer circuits of the first and second channels, the training circuit performing at least one training operation while the testing sequences overlap in time.

19. The data processing system of claim 15, wherein the test circuit generates testing sequences including read commands on one of the channels while write commands are on the other channel.

20. The data processing system of claim 15, wherein the test circuit generates testing sequences including read commands on one of the channels while read commands are on the other channel.
